(19) United States
(12) Patent Application Publication
(10) Pub. No.: US 2023/0361722 A1
(43) Pub. Date: Nov. 9, 2023

(54) DPD APPARATUS AND METHOD APPLICABLE TO 5G BROADBAND MIMO SYSTEM

(71) Applicant: NANJING HOWKING TECHNOLOGY CO., LTD., Nanjing (CN)

(72) Inventors: Ping CHEN, Nanjing (CN); CONGRUI WANG, Nanjing (CN); JINMING PENG, Nanjing (CN); YUFENG QIN, Nanjing (CN)

(21) Appl. No.: 17/311,360

(22) PCT Filed: May 7, 2021
(86) PCT No.: PCT/CN2021/091983

§ 371 Date: Jun. 7, 2021

(30) Foreign Application Priority Data
Jan. 25, 2021 (CN) 202110098364.8

(51) Int. Cl. H03F 1/32; H03F 3/189; H03F 3/213

(52) U.S. Cl. CPC H03F 1/3247; H03F 3/189; H03F 3/213

(57) ABSTRACT

The present disclosure relates to the technical field of wireless communications, in particular, a digital predistortion (DPD) apparatus applicable to a 5G broadband multiple-input multiple-output (MIMO) system. The DPD apparatus includes a data processing module, a digital-to-analog conversion module, a signal output module, a signal feedback module, and an analog-to-digital conversion module; the signal feedback module is to ensure that at least two feedback paths are directed to a DPD feedback signal. The first feedback path is a main feedback loop, and the second feedback path is an auxiliary feedback loop. The present disclosure has the advantages of occupying a few of hardware resources, being capable of monitoring a DPD feedback loop signal in real time, and making a response in time.

### TECHNICAL FIELD

The present disclosure relates to the technical field of wireless communications, in particular, a digital predistortion (DPD) apparatus and method applicable to a 5G broadband multiple-input multiple-output (MIMO) system.

### BACKGROUND

With the development of wireless communication technologies, requirements for the data transmission rate continue to increase. In order to achieve high-capacity data transmission on scarce spectrum resources, communication systems now use high-bandwidth, high-order modulation, multiple-input multiple-output (MIMO), and other technologies. This non-constant envelope modulation and multi-carrier technology will lead to a peak-to-average ratio of a modulated signal; and due to high-broadband application, higher requirements are placed on the linearity of a radio frequency power amplifier. In order to improve the efficiency of the radio frequency power amplifier and reduce the power consumption of the system, the current most effective way is to perform digital predistortion (DPD) processing on a digital signal.

When a DPD device is used, an output signal of the radio frequency power amplifier needs to be fed back; the feedback signal is digitally processed and then sent to a DPD kernel algorithm. A DPD model extracts a predistortion coefficient by means of iterative processing of the feedback signal and the output signal, corrects the predistortion of the input signal, and then finally obtains a linear signal output through a nonlinear radio frequency power amplifier.

The distortion of the power amplifier is composed of amplitude-amplitude distortion (AM-AM), amplitude-phase distortion (AM-PM), and distortion caused by the memory effect. At present, 5G signals all use a larger bandwidth. A wider system bandwidth leads to more obvious memory effect of the radio frequency power amplifier, more serious nonlinear effect, and more complicated linearization process. In addition, new communication systems have increasingly high delay requirements, and DPD models are also required to be able to quickly respond to the distortion caused by the radio frequency power amplifier.

At present, for DPD devices of multi-channel MIMO systems or multi-band systems, a feedback signal loop mainly adopts a one-path separate feedback method and a multi-path switching feedback method. The one-path separate feedback method has a higher hardware requirement, and requires a separate feedback loop of each radio frequency amplifier, down-conversion, analog-to-digital conversion and other resources for each RF amplifier. The advantage is that a transmitted signal can be monitored in real time and responded in time. The multi-path switching method feeds back each signal in a polling manner. When there are a larger number of channels, one polling cycle takes a long time, and a few of hardware resources are occupied, but the response is not made in time.

### SUMMARY

The present disclosure provides a digital predistortion (DPD) device and method applicable to a 5G broadband multiple-input multiple-output (MIMO) system, which have the advantages of being able to monitor a DPD feedback loop signal in real time and make a response in time.

In order to achieve the purpose of the present disclosure, the technical solution used is that: A DPD apparatus applicable to a 5G broadband MIMO system includes a data processing module, a digital-to-analog conversion module, a signal output module, a signal feedback module and an analog-to-digital conversion module.

The data processing module performs iterative processing on a baseband input signal and a feedback signal to acquire a predistortion coefficient, performs DPD processing on the baseband signal through a built DPD model, and is then connected to the digital-to-analog conversion module;
the digital-to-analog conversion module performs digital-to-analog conversion on the predistortion signal processed by the data processing module, filters the predistortion signal, performs inphase-quadrature phase (IQ) modulation, and is connected to the signal output module;
the signal output module performs power amplification and filtering processing on the signal input by the digital-to-analog conversion module, and then transmits and outputs the signal via an antenna;
the signal feedback module is to ensure that at least two feedback paths are directed to a feedback signal, wherein the first feedback path is a main feedback loop, and the second feedback path is an auxiliary feedback loop;
the main feedback loop is multi-path output signal sharing feedback by a switching mode. One path of output signal feedback can be only switched on at one time to realize main adjustment of a DPD coefficient. When all channels output normally, the channels are switched on in a polling manner, and the DPD coefficients of the various channels are updated in time to ensure that the signals output by the updated channels are highest in linearity;
the auxiliary feedback loop performs feedback in a manner of new radio coupling or combination after a plurality of output signals are coupled; a feedback signal contains a multi-path output signal combination used for real-time monitoring of signals and acting as a preselector for output signal distortion channels; when a relatively serious distortion signal is output from a channel, it is determined that the channel is a distortion signal output channel; the main feedback loop is switched to the channel with the most serious output signal distortion to quickly complete the main adjustment of the DPD coefficient; the auxiliary feedback loop also serves as auxiliary adjustment of the DPD coefficient, and finely adjusts the DPD coefficient in case of relatively small distortion of the output signal;
the analog-to-digital conversion module demodulates the feedback signal of the signal feedback module, then performs analog-to-digital conversion, and is connected to the data processing module.

As an optimization solution of the present disclosure, the signal feedback module includes a plurality of coupling units, a plurality of transmitting antennas and a radio frequency switch. The plurality of coupling units receive a plurality of power signals output by the signal output module and output a plurality of transmitted signals and a plurality of coupling signals; the plurality of transmitting antennas are connected to the plurality of coupling units, receive the plurality of transmitted signals, and output the plurality of transmitted signals in a radiation manner, the main feedback loop receives the plurality of coupling signals and outputs one coupling signal through switching of the radio frequency switch; the coupling signal is subjected to IQ demodulation, low pass filtering and ADC conversion and enters the data processing module; the auxiliary feedback loop receives, through one coupling antenna, the plurality of transmitted signals that are combined to form one path of feedback signal; and the feedback signal enters the data processing module after IQ demodulation, low pass filtering and ADC conversion.

As an optimization solution of the present disclosure, the data processing module includes a plurality of DPD processing modules, two DPD adaptation modules and one controller; the plurality of DPD processing modules process a plurality of baseband signals and compensate an introduced nonlinear distortion; the two DPD adaptation modules receive two paths of digital feedback signals from the main feedback loop and the auxiliary feedback loop; a DPD output signal is adjusted through the plurality of DPD processing modules; and the controller receives the digital baseband signals and the digital feedback signals, and controls the radio frequency switch according to states of the feedback signals.

As an optimization solution of the present disclosure, the signal feedback module further includes a plurality of one-to-two power dividers; the plurality of one-to-two power dividers receive the plurality of coupling signals sent by the coupling units, divide each coupling signal into two signals, and output two paths of a plurality of power division coupling signals; one path of the plurality of power division coupling signals are switched through the radio frequency switch to be used as the main feedback loop, and the other path of the plurality of power division coupling signals are combined through a combiner to be used as the auxiliary feedback signal.

In order to achieve the purpose of the present disclosure, the technical solution used is that: A DPD method applicable to a 5G broadband MIMO system includes the following steps:
Step S01: monitoring the signal power of each radio frequency channel in real time according to an auxiliary feedback loop signal, and estimating a nonlinear distortion degree of a radio frequency power amplifier of each radio frequency channel;
Step S02: acquiring the radio frequency channel with the most serious nonlinear distortion, and switching a main feedback loop to the most seriously distorted radio frequency channel;
Step S03: acquiring accurate output power and a nonlinear distortion state of the channel through the main feedback loop, acquiring a channel coefficient by means of a DPD model of the improved invention, quickly updating the radio frequency channel coefficient, and maintaining linear outputting of radio frequency signals of the channel; and
Step S04: continuing to acquire other radio frequency channels with the most serious nonlinear distortion according to the auxiliary feedback loop signal, and updating channel coefficients.

As an optimization solution of the present disclosure, the DPD model is a dynamic deviation dimension reduction method, which is expressed as.

$$y ( n ) = {\sum }_{p = 1}^{p} {h}_{p , 0} ( 0 , … , 0 ) {x}^{p} ( n ) + {\sum }_{p = 1}^{p} \{ {\sum }_{r = 1}^{p} [ {x}^{p - r} ( n ) {\sum }_{{i}_{2} = 1}^{M} … {\sum }_{{i}_{r} = {i}_{r - 1}}^{M} {h}_{p , r} ( 0 , … , 0 , {i}_{1} , … , {i}_{r} ) {\prod }_{j = 1}^{r} x ( n - {i}_{j} ) ] \}$$

where x(n) and y(n) respectively represent input and output composite envelopes; h_{p,0}(0, . . . 0) and h_{p,r}(0, . . . , 0, i₁, . . . , iᵣ) represents a p-order Volterra kernel; P is a nonlinear order (an odd number); and M represents a memory depth.

The present disclosure has the active effects as follows.
1) a two-feedback combined form of multi-path switching and multi-signal combination is used, so that the disadvantage that more hardware resources are occupied because a plurality of signals are fed back separately is reduced, and the problem of slow response caused by polling feedback of the plurality of signals is improved;
2) compared with a traditional multi-channel system, the present disclosure adds a fewer of hardware resources, so that the cost is lower, and the method is simple and easy to realize;
3) by the adoption of a dual feedback form, the present disclosure improves the reliability of the feedback system;
4) this invention monitors the communication quality and the channel usage rate of each transmitting channel in the MIMO system in real time when applied to a multi-channel MIMO system of a broadband;
5) this invention is applied to a beamforming system, and can also be used to monitor in real time phase information of signals output by the various channels and monitor a combination effect of beamforming signals; and
6) the present disclosure uses a novel DPD model algorithm, so that higher accuracy is maintained, the model complexity is reduced, hardware logic resources are saved, and the response speed of the system is increased.

### BRIEF DESCRIPTION OF THE DRAWINGS

The present disclosure is further described in detail below in combination with accompanying drawings and specific implementation modes.

FIG. 1 is an overall block diagram of a digital predistortion (DPD) apparatus applicable to a 5G broadband multiple-input multiple-output (MIMO) system of the present disclosure;

FIG. 2 is a flowchart of a DPD method applicable to a 5G broadband MIMO system of the present disclosure;

FIG. 3 illustrates a functional block diagram of the apparatus of the present disclosure; and

FIG. 4 illustrates another functional block diagram of the apparatus of the present disclosure.

Reference signs in the drawings: 1: data processing module; 2: digital-to-analog conversion module; 3: signal output module; 4: signal feedback module; 5: analog-to-digital conversion module.

### DESCRIPTION OF THE EMBODIMENTS

As shown in FIG. 1, the present disclosure discloses a DPD apparatus applicable to a 5G broadband MIMO system, including a data processing module 1, a digital-to-analog conversion module 2, a signal output module 3, a signal feedback module 4 and an analog-to-digital conversion module 5;
the data processing module 1 performs iterative processing on a baseband input signal and a feedback signal to acquire a predistortion coefficient, performs DPD processing on the baseband signal through a built DPD model, and is then connected to the digital-to-analog conversion module 2;
the digital-to-analog conversion module 2 performs digital-to-analog conversion on the predistortion signal processed by the data processing module 1, filters the predistortion signal, performs quadrature IQ modulation, and is connected to the signal output module 3;
the signal output module 3 performs power amplification and filtering processing on the signal input by the digital-to-analog conversion module 2, and then transmits and outputs the signal via an antenna;
the signal feedback module 4 is to ensure that at least two feedback paths are directed to a feedback signal, wherein the first feedback path is a main feedback loop, and the second feedback path is an auxiliary feedback loop;
the main feedback loop is multi-path output signal sharing feedback by a switching mode. One path of output signal feedback can be only switched on at one time to realize main adjustment of a DPD coefficient. When all channels output normally, the channels are switched on in a polling manner, and the DPD coefficients of the various channels are updated in time to ensure that the signals output by the updated channels are highest in linearity;
the auxiliary feedback loop performs feedback in a manner of new radio coupling or combination after a plurality of output signals are coupled; a feedback signal contains a multi-path output signal combination used for real-time monitoring of signals and acting as a preselector for output signal distortion channels; when a relatively serious distortion signal is output from a channel, it is determined that the channel is a distortion signal output channel; the main feedback loop is switched to the channel with the most serious output signal distortion to quickly complete the main adjustment of the DPD coefficient; the auxiliary feedback loop also serves as auxiliary adjustment of the DPD coefficient, and finely adjusts the DPD coefficient in case of relatively small distortion of the output signal;
the analog-to-digital conversion module 5 demodulates the feedback signal of the signal feedback module 4, then performs analog-to-digital conversion, and is connected to the data processing module 1.

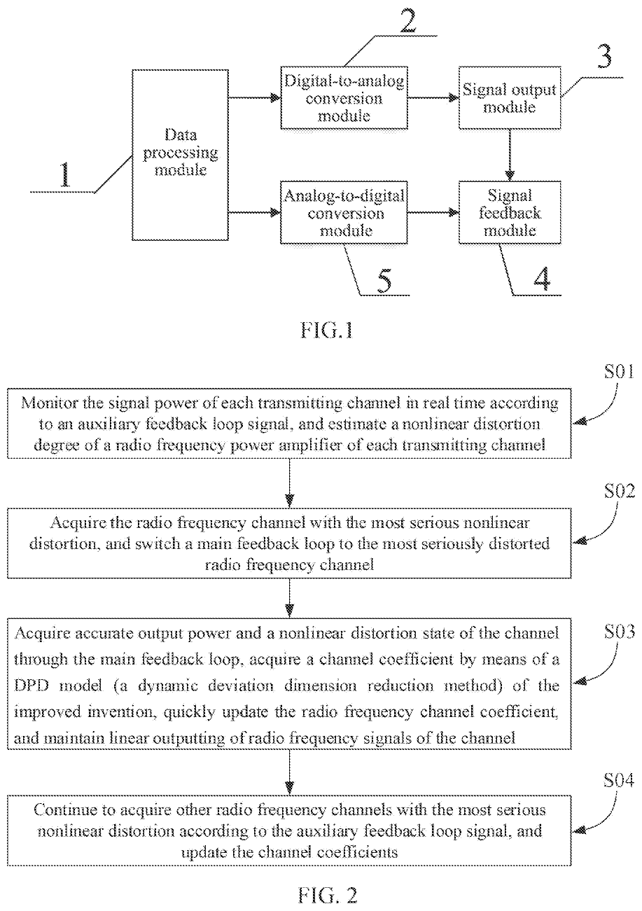

As shown in FIG. 2, a DPD method applicable to a 5G broadband MIMO system includes the following steps.

Step S01: the signal power of each radio frequency channel is monitored in real time according to an auxiliary feedback loop signal, and a nonlinear distortion degree of a radio frequency power amplifier of each radio frequency channel is estimated.

The auxiliary feedback loop signal includes feedback signals of a plurality of radio frequency channels. The auxiliary feedback loop signal is formed by combining a plurality of radio frequency channel feedback signals. Since each radio frequency channel signal included in the auxiliary feedback loop signal and the radio frequency channel transmitted signal have been calibrated, the state of each radio frequency channel signal can be obtained by decomposed calculation by real-time monitoring for the signals of the auxiliary feedback loop; and furthermore, the nonlinear distortion degree of the radio frequency power amplifier of each channel can be estimated through the state of the signal of the feedback loop.

Step S02: the radio frequency channel with the most serious nonlinear distortion is acquired, and a main feedback loop to the most seriously distorted radio frequency channel.

The main feedback loop is a feedback path having the feedback loop signal that only includes one radio frequency channel signal. Since the main feedback loop signal only contains one channel signal, various state of a radio frequency channel can be reflected more accurately. The nonlinear distortion degrees of the radio frequency power amplifiers of the various channels estimated according the step S01 are sorted according to the nonlinear distortion degrees of the various radio frequency channels to acquire the radio frequency channel with the signal having the most serious nonlinear distortion from among all the radio frequency channels, and the feedback path of the main feedback loop is switched to the radio frequency channel with the most seriously distorted signal.

Step S03: accurate output power and a nonlinear distortion state of the channel are acquired through the main feedback loop; a channel coefficient is acquired by means of a DPD model of the improved invention; the radio frequency channel coefficient is quickly updated; and linear outputting of radio frequency signals of the channel is maintained.

The main feedback loop has been connected to the radio frequency channel with the most serious nonlinear distortion. The accurate state of the radio frequency channel signal is acquired through calculation, and includes the radio frequency output power, and a nonlinear distortion state caused by the power amplifier. A DPD model coefficient of the radio frequency channel is acquired by a dynamic deviation dimension reduction method; updating of the DPD model coefficient of the radio frequency channel can be quickly completed; and the linear outputting state of the radio frequency channel is maintained.

The dynamic deviation dimension reduction method provides an effective order reduction method. This method removes the high-order dynamic memory effect as the influence of the nonlinear dynamic memory effect will decrease with the increase of a nonlinear order. Unlike a classical Volterra model, the number of coefficients increases exponentially with the nonlinear order and memory length. In a reduced-order model, the number of coefficients increases almost linearly with the nonlinear order and memory length. The Volterra model can be used to accurately characterize the power amplifiers with static strong nonlinear, long-term linear and low-order nonlinear memory effects since the model complexity is significantly reduced after the truncation of the high-order dynamic memory effect. By regrouping Volterra coefficients, different dynamic orders can be controlled and separated, while keeping the simplicity of the model extraction process. This method can significantly reduce the complexity of classical Volterra models without loss of model fidelity, and both static nonlinearity and dynamic effects of different orders can be identified. The dynamic deviation dimension method can be expressed as:

$$y ( n ) = {\sum }_{p = 1}^{p} {h}_{p , 0} ( 0 , … , 0 ) {x}^{p} ( n ) + {\sum }_{p = 1}^{p} \{ {\sum }_{r = 1}^{p} [ {x}^{p - r} ( n ) {\sum }_{{i}_{2} = 1}^{M} … {\sum }_{{i}_{r} = {i}_{r - 1}}^{M} {h}_{p , r} ( 0 , … , 0 , {i}_{1} , … , {i}_{r} ) {\prod }_{j = 1}^{r} x ( n - {i}_{j} ) ] \}$$

where x(n) and y(n) respectively represent composite envelopes of an input and an output. h_{p,0}(0, . . . 0) and h_{p,r}(0, . . . , 0, i₁, . . . , iᵣ) represent a p-order Volterra kernel. P is a nonlinear order (an odd number), and M represents a memory depth

Many radio frequency power amplifiers have the characteristic that their dynamic effects attenuate with the increase of the nonlinear order, so that the model complexity can be obviously reduced by eliminating the high-order dynamic effect, i.e., the value of r is maintained within a smaller range (r=1,2)

If dynamic r is equal to 1, the first-order model can be expressed as

$$y ( n ) = {\sum }_{p = 1}^{p} {h}_{p , 0} ( 0 , … , 0 ) {x}^{p} ( n ) + {\sum }_{p = 1}^{p} {x}^{p - 1} ( n ) {\sum }_{i = 1}^{M} {h}_{p , 1} ( 0 , … , 0 , i ) x ( n - i )$$

In order to accurately model the power amplifier in the complicated baseband, the model in the formula needs to be converted into a low pass equivalent format:

$$\tilde{y} ( n ) = {\sum }_{p = 0}^{\frac{p - 1}{2}} {\sum }_{i = 0}^{M} {h}_{2 p + 1 , 1} {\vert \tilde{x} ( n ) \vert}^{2 p} + \tilde{x} ( n - i ) {\sum }_{p = 0}^{\frac{p - 1}{2}} {\sum }_{i = 0}^{M} {h}_{2 p + 1 , 2} {\vert \tilde{x} ( n ) \vert}^{2 ( p - 1 )} {\tilde{x}}^{2} ( n ) {\tilde{x}}^{*} ( n - i )$$

where \tilde{x}(n) and \tilde{y}(n) respectively represent baseband composite envelopes of an input and an output.

Step S04: other radio frequency channels with the most serious nonlinear distortion are continued to be acquired according to the auxiliary feedback loop signal, and channel coefficients are updated.

At the step S03, the coefficients of the radio frequency channels with the most serious nonlinear distortion have been updated, and the specified radio frequency channels have completed linear outputting of the signals Meanwhile, the auxiliary feedback loop has also acquired the currently specified other radio frequency channels with the most serious nonlinear distortion, and then switches the main feedback loop to the current radio frequency channel with the most serious nonlinear distortion to complete the updating of the coefficients of the current radio frequency channel. All the above steps are repeated to keep the linear outputting of all the radio frequency channel signals all the time.

The data processing module 1 is mainly, but is not limited to, a field programmable logic gate array (FPGA), and is used to perform united processing on a baseband input signal, an output feedback signal, and signals of various modules. The data processing module 1 mainly realizes baseband signal preprocessing, DPD model realization, output feedback signal analysis, module control, digital-to-analog conversion control, analog-to-digital conversion control, local frequency control, and signal gain control.

The baseband signal preprocessing is to parse instructions and data from an input baseband signal, preprocess the data of the baseband input signal according to different instructions, and divide the data into two paths, where one path is used to input the DPD model and perform DPD preprocessing, and the other path is used to perform iterative operation on the feedback signals to acquire the coefficients of the radio frequency channel.

The DPD model realization is to use an FPGA hardware description language logic algorithm to realize this algorithm according to the dynamic deviation dimension reduction method of the step S03 in the method of the present disclosure.

The feedback signal analysis means that after a signal is output by a radio frequency power amplifier, the signal is returned to the data processing module through the feedback loop for digital quantification, and signal information of the various channels is calculated according to the digitally quantized data, including the amplitude and phase information of the various radio frequency channel signals, and the nonlinear distortion degrees of the radio frequency channels.

The module control means that determination is performed according to the signal state obtained after the above-mentioned feedback signal analysis, and a further operation is performed according to a determination result. For example, the radio frequency channel with the most serious nonlinear distortion is acquired according to the nonlinear distortion degree of the radio frequency channel, and a radio frequency switch of the main feedback loop is controlled to switch to the radio frequency channel.

The digital-to-analog conversion control means that when the digital baseband signal subjected to DPD model processing is converted into an analog signal, the signal is subjected to format conversion, alignment, synchronization, etc.

The analog-to-digital conversion control means that when the feedback signal is converted into a digital signal, the signal is subjected to synchronization, alignment, format conversion, etc.

The local frequency control is to configure a local frequency used for up- and down-conversion of a radio frequency.

The signal gain control means gain configuration processing for transmitting and receiving channels during communication.

The digital-to-analog conversion module 2 converts a predistortion signal processed by the data processing module into an analog signal, filters the predistortion signal, performs inphase-quadrature phase (IQ) modulation, filters the modulated radio frequency signal again, and is connected to the signal output module 3.

The signal output module 3 performs power amplification, filtering processing, and transmitting-receiving isolation on the signal input by the digital-to-analog conversion module 2, and then transmits and outputs the signal via an antenna. For a time division duplexing (TDD) system, the transmitting-receiving isolation can use a circulator and a radio frequency switch element. For a frequency division duplexing (FDD), the transmitting-receiving isolation can use a multiplexer.

The signal feedback module 4 is to ensure that at least two feedback paths are directed to a feedback signal, wherein the first feedback path is a main feedback loop, and the second feedback path is an auxiliary feedback loop. In the present embodiment, the signal output by the radio frequency power amplifier is fed back. The feedback loop is composed of two paths, one of which is for each separate feedback for each radio frequency channel. The feedback signal of each radio frequency channel is switched by the radio frequency switch to a demodulator, is then filtered after the down-conversion, and enters an analog-to-digital converter (ADC). Therefore, the feedback loop has only one signal connected to the ADC at the same time and converted into a digital signal. This feedback signal is called the main feedback loop that is used for main adjustment of a DPD coefficient; when all channels output normally, the channels are switched on in a polling manner, and the DPD coefficients of the various channels are updated in time to ensure that the signals output by the updated channels are highest in linearity. The other feedback signal is fed back after a plurality of feedback loops are combined. There are generally not more than 8 radio frequency channels in the combined feedback loop. There are various methods for combining a plurality of radio frequency channels of the feedback loop, which can be new radio coupling or combination through a combiner after a plurality of output signals are coupled. This feedback loop is called the auxiliary feedback loop used to monitor signals in real time and serving as a preselector for output signal distortion channels. When a relatively serious distortion signal is output from a channel, it is determined that the channel is a distortion signal output channel; the main feedback loop is switched to the channel with the most serious output signal distortion to quickly complete the main adjustment of the DPD coefficient; the auxiliary feedback loop also serves as auxiliary adjustment of the DPD coefficient, and finely adjusts the DPD coefficient in case of relatively small distortion of the output signal.

The analog-to-digital conversion module 5 couples the signals output by the power amplifiers, and the coupled signal and a local signal are subjected to IQ demodulation and filtration and then subjected to analog-to-digital conversion into digital signals which are input to the data processing module.

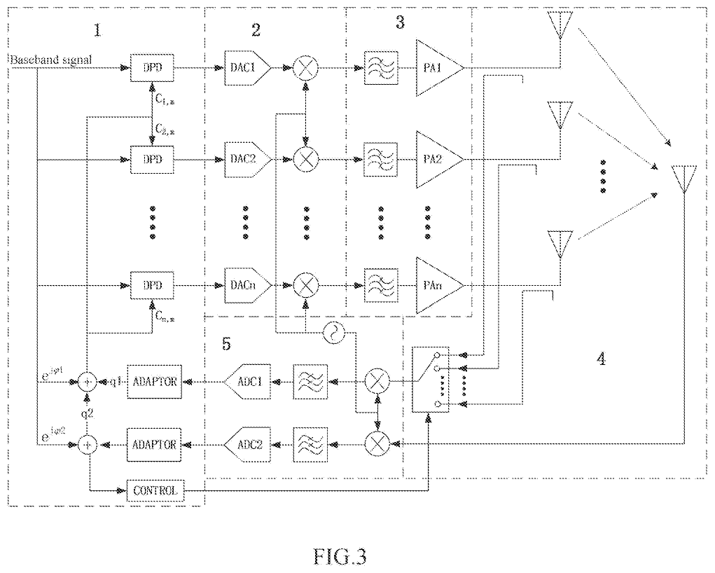

The example as shown in FIG. 3 includes one data processing module, a plurality of DACs, a plurality of up-conversion mold modulators, one local oscillation source, a plurality of radio frequency filters, a plurality of radio frequency power amplifiers, a plurality of coupling units, a plurality of transmitting antennas, one main feedback loop and one auxiliary feedback loop.

The data processing module includes a plurality of DPD processing channels and outputs a plurality of digital baseband signals;
the plurality of DACs are connected to the plurality of DPD processing channels, receives the plurality of digital baseband signals and converts the signals into analog baseband signals;
the plurality of up-conversion modulators are connected to the plurality of DACs, receives the plurality of analog baseband signals and outputs modulated radio frequency signals;
the local oscillation source is connected to the plurality of up-conversion modulators and outputs local oscillation signals for up-conversion;
the plurality of radio frequency filters are connected to the plurality of up-conversion modulators, receives the plurality of radio frequency signals, filters the radio frequency signals, and outputs the filtered radio frequency signals;
the plurality of radio frequency power amplifiers are connected to the plurality of radio frequency filters, receives the filtered radio frequency signals, and amplifies and outputs power signals;
the plurality of coupling units are connected to the plurality of radio frequency power amplifiers, receives the plurality of power signals, and outputs a plurality of transmitted signals and a plurality of coupling signals;
the plurality of transmitting antennas are connected to the plurality of coupling units, receives the plurality of transmitted signals, and outputs the plurality of transmitted signals in a radiation manner;
the main feedback loop receives the plurality of coupling signals and outputs one coupling signal through switching of the radio frequency switch, and the coupling signal is subjected to IQ demodulation, low pass filtering and ADC conversion, and enters the data processing module;
the auxiliary feedback loop receives, through one coupling antenna, the plurality of transmitted signals that are combined to form one path of feedback signal, and the signal is subjected to IQ demodulation, low pass filtering and ADC conversion, and enters the data processing module.

The data processing module 1 includes a plurality of DPD processing modules, two DPD adaptation modules and one controller; the plurality of DPD processing modules process a plurality of baseband signals and compensate a nonlinear distortion introduced by the plurality of radio frequency power amplifiers; the two DPD adaptation modules receive two paths of digital feedback signals from the main feedback loop and the auxiliary feedback loop; a DPD output signal is adjusted through the plurality of DPD processing modules; and the controller receives the digital baseband signals and the digital feedback signals, and controls the radio frequency switch according to states of the feedback signals.

The signal feedback module 4 includes a plurality of coupling units, a plurality of transmitting antennas and a radio frequency switch. The plurality of coupling units receive a plurality of power signals output by the signal output module 3 and output a plurality of transmitted signals and a plurality of coupling signals; the plurality of transmitting antennas are connected to the plurality of coupling units, receive the plurality of transmitted signals, and output the plurality of transmitted signals in a radiation manner, the main feedback loop receives the plurality of coupling signals and outputs one coupling signal through switching of the radio frequency switch; the coupling signal is subjected to IQ demodulation, low pass filtering and ADC conversion and enters the data processing module; the auxiliary feedback loop receives, through one coupling antenna, the plurality of transmitted signals that are combined to form one path of feedback signal; and the feedback signal enters the data processing module after IQ demodulation, low pass filtering and ADC conversion.

The key to the realization of the example shown in FIG. 3 lies in the design of the transmitting antenna and the coupling antenna. The coupling antenna is designed to be closer to the transmitting antenna of each channel. The coupling coefficients of the transmitting antenna of each channel and the coupling antenna of each channel have been calibrated. Amplitude and phase differences between an input signal and a feedback signal of each transmitting channel have also been calibrated. Therefore, the state of the radio frequency signal of each channel can be calculated by monitoring the combined feedback signal. When the radio frequency power amplifier of each channel is monitored to work in a linear state, the DPD coefficient of each channel is adjusted, and an input signal is not predistorted; and when the power amplifier of a certain radio frequency channel is monitored to work in a nonlinear state, the DPD coefficient of the radio frequency channel is adjusted, and the input signal of this channel is predistorted; and finally, the output of the channel is linearized.

The feedback loop described in the example in FIG. 3 is designed in the MIMO system, which can not only be used for DPD processing, but also for real-time monitoring of communication quality and channel usage rate of each transmitting channel in the MIMO system. This design is also used to monitor in real time phase information of signals output by the various channels in a beamforming system, and monitor a combination effect of beamforming signals in real time.

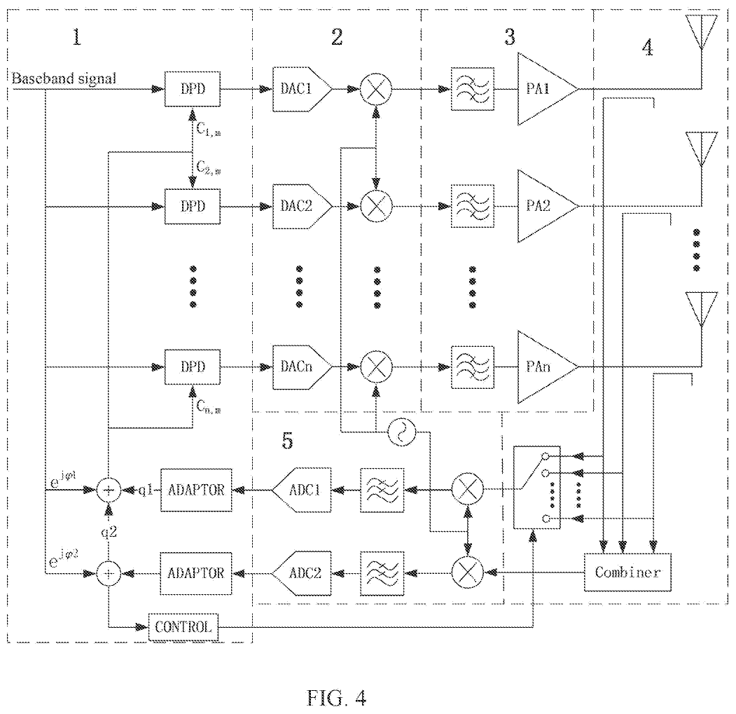

Another example as shown in FIG. 4 includes one data processing module, a plurality of DACs, a plurality of up-conversion mold modulators, one local oscillation source, a plurality of radio frequency filters, a plurality of radio frequency power amplifiers, a plurality of coupling units, a plurality of one-to-two power dividers, a plurality of transmitting antennas, one main feedback loop and one auxiliary feedback loop. The data processing module, the plurality of DACs, the plurality of up-conversion mold modulators, the local oscillation source, the plurality of radio frequency filters, the plurality of power amplifiers, the plurality of coupling units, and the plurality of transmitting antennas are the same as those in FIG. 3.

The signal feedback module 4 further includes a plurality of one-to-two power dividers; the plurality of one-to-two power dividers receive the plurality of coupling signals sent by the coupling units, divide each coupling signal into two signals, and output two paths of a plurality of power division coupling signals; one path of the plurality of power division coupling signals are switched through the radio frequency switch to be used as the main feedback loop, and the other path of the plurality of power division coupling signals are combined through a combiner to be used as the auxiliary feedback signal.
the main feedback loop receives one path of the plurality of power division coupling signals and outputs one feedback signal through switching of the radio frequency switch, and the feedback signal is subjected to IQ demodulation, low pass filtering and ADC conversion, and enters the data processing module;
the auxiliary feedback loop receives the other path of the plurality of power division coupling signals which are combined, through a combiner, into one feedback signal including the plurality of power division coupling signals, and the feedback signal is subjected to IQ demodulation, low pass filtering and ADC conversion, and enters the data processing module.

In the example shown in FIG. 4, each radio frequency channel signal is separately coupled after being output by the power amplifier. The signal coupled by each radio frequency channel is then divided into two paths. One path of coupling signal serves as the main feedback loop via the radio frequency switch, and the other path of coupling signal serves as the auxiliary feedback loop after being combined through the combiner. Since the path of the feedback signal of each radio frequency channel has been determined, and the amplitude and phase differences between the input signal and the feedback signal are also determined after all the radio frequency channels have been calibrated, the state of the radio frequency signal of each channel can be calculated by monitoring the combined auxiliary feedback signal. The working principle is the same as that shown in FIG. 3. The input signals of the plurality of radio frequency channels are predistorted by adjusting the DPD coefficients of the plurality of radio frequency channels in real time, and finally the outputs of the plurality of radio frequency channels are linearized.

The specific embodiments described above further describe the purposes, technical solutions and beneficial effects of the present disclosure in further detail. It should be understood that the above descriptions are only specific embodiments of the present disclosure and are not intended to limit the present disclosure. Any modifications, equivalent replacements, improvements, etc. made within the spirit and principle of the present disclosure should fall within the protection scope of the present disclosure.

What is claimed is:

1. A digital predistortion (DPD) apparatus applicable to a 5G broadband multiple-input multiple-output (MIMO) system, comprising a data processing module (1), a digital-to-analog conversion module (2), a signal output module (3), a signal feedback module (4) and an analog-to-digital conversion module (5), wherein
the data processing module (1) performs iterative processing on a baseband input signal and a feedback signal to acquire a predistortion coefficient, performs DPD processing on the baseband signal through a built DPD model, and is then connected to the digital-to-analog conversion module (2);
the digital-to-analog conversion module (2) performs digital-to-analog conversion on the predistortion signal processed by the data processing module (1), filters the predistortion signal, performs inphase-quadrature phase (IQ) modulation, and is connected to the signal output module (3);
the signal output module (3) performs power amplification and filtering processing on the signal input by the digital-to-analog conversion module (2), and then transmits and outputs the signal via an antenna;
the signal feedback module (4) is to ensure that at least two feedback paths are directed to a feedback signal, wherein the first feedback path is a main feedback loop, and the second feedback path is an auxiliary feedback loop;
the main feedback loop is multi-path output signal sharing feedback by a switching mode. One path of output signal feedback can be only switched on at one time to realize main adjustment of a DPD coefficient. When all channels output normally, the channels are switched on in a polling manner, and the DPD coefficients of the various channels are updated in time to ensure that the signals output by the updated channels are highest in linearity;
the auxiliary feedback loop performs feedback in a manner of new radio coupling or combination after a plurality of output signals are coupled; a feedback signal contains a multi-path output signal combination used for real-time monitoring of signals and acting as a preselector for output signal distortion channels; when a relatively serious distortion signal is output from a channel, it is determined that the channel is a distortion signal output channel; the main feedback loop is switched to the channel with the most serious output signal distortion to quickly complete the main adjustment of the DPD coefficient; the auxiliary feedback loop also serves as auxiliary adjustment of the DPD coefficient, and finely adjusts the DPD coefficient in case of relatively small distortion of the output signal;
the analog-to-digital conversion module (5) demodulates the feedback signal of the signal feedback module (4), then performs analog-to-digital conversion, and is connected to the data processing module (1).

2. The DPD apparatus applicable to the 5G broadband MIMO system according to claim 1, wherein the signal feedback module (4) comprises a plurality of coupling units, a plurality of transmitting antennas and a radio frequency switch; the plurality of coupling units receive a plurality of power signals output by the signal output module (3) and output a plurality of transmitted signals and a plurality of coupling signals; the plurality of transmitting antennas are connected to the plurality of coupling units, receive the plurality of transmitted signals, and output the plurality of transmitted signals in a radiation manner, the main feedback loop receives the plurality of coupling signals and outputs one coupling signal through switching of the radio frequency switch; the coupling signal is subjected to IQ demodulation, low pass filtering and ADC conversion and enters the data processing module; the auxiliary feedback loop receives, through one coupling antenna, the plurality of transmitted signals that are combined to form one path of feedback signal; and the feedback signal enters the data processing module after IQ demodulation, low pass filtering and ADC conversion.

3. The DPD apparatus applicable to the 5G broadband MIMO system according to claim 2, wherein the data processing module comprises a plurality of DPD processing modules, two DPD adaptation modules and one controller; the plurality of DPD processing modules process a plurality of baseband signals and compensate an introduced nonlinear distortion; the two DPD adaptation modules receive two paths of digital feedback signals from the main feedback loop and the auxiliary feedback loop; a DPD output signal is adjusted through the plurality of DPD processing modules; and the controller receives the digital baseband signals and the digital feedback signals, and controls the radio frequency switch according to states of the feedback signals.

4. The DPD apparatus applicable to the 5G broadband MIMO system according to claim 3, wherein the signal feedback module (4) further comprises a plurality of one-to-two power dividers; the plurality of one-to-two power dividers receive the plurality of coupling signals sent by the coupling units, divide each coupling signal into two signals, and output two paths of a plurality of power division coupling signals; one path of the plurality of power division coupling signals are switched through the radio frequency switch to be used as the main feedback loop, and the other path of the plurality of power division coupling signals are combined through a combiner to be used as the auxiliary feedback signal.

5. A DPD method applicable to a 5G broadband MIMO system, comprising the following steps:
Step S01: monitoring the signal power of each radio frequency channel in real time according to an auxiliary feedback loop signal, and estimating a nonlinear distortion degree of a radio frequency power amplifier of each radio frequency channel,
Step S02: acquiring the radio frequency channel with the most serious nonlinear distortion, and switching a main feedback loop to the most seriously distorted radio frequency channel;
Step S03: acquiring accurate output power and a nonlinear distortion state of the channel through the main feedback loop, acquiring a channel coefficient by means of a DPD model of the improved invention, quickly updating the radio frequency channel coefficient, and maintaining linear outputting of radio frequency signals of the channel; and
Step S04: continuing to acquire other radio frequency channels with the most serious nonlinear distortion according to the auxiliary feedback loop signal, and updating channel coefficients.

6. The DPD method applicable to the 5G broadband MIMO system according to claim 5, wherein the DPD model is a dynamic deviation dimension reduction method, which is expressed as:
$$y ( n ) = {\sum }_{p = 1}^{p} {h}_{p , 0} ( 0 , … , 0 ) {x}^{p} ( n ) + {\sum }_{p = 1}^{p} \{ {\sum }_{r = 1}^{p} [ {x}^{p - r} ( n ) {\sum }_{{i}_{2} = 1}^{M} … {\sum }_{{i}_{r} = {i}_{r - 2}}^{M} {h}_{p , r} ( 0 , … , 0 , {i}_{1} , … , {i}_{r} ) {\prod }_{j = 1}^{r} x ( n - {i}_{j} ) ] \}$$
where x(n) and y(n) respectively represent input and output composite envelopes; h_{p,0}(0, . . . 0) and h_{p,r}(0, . . . , 0,i₁, . . . , iᵣ) represents a p-order Volterra kernel; P is a nonlinear order, P is an odd number, and M represents a memory depth.
